(19) United States
(12) Patent Application Publication
(10) Pub. No.: US 2022/0208799 A1
(43) Pub. Date: Jun. 30, 2022

(54) ARRAY SUBSTRATE, FABRICATING METHOD THEREOF, AND DISPLAY DEVICE

(71) Applicant: Shenzhen China Star Optoelectronics Semiconductor Display Technology Co., Ltd., Shenzhen (CN)

(72) Inventors: Letao ZHANG, Shenzhen (CN); Liangfen ZHANG, Shenzhen (CN); Qiankun XU, Shenzhen (CN); Xiaoxing ZHANG, Shenzhen (CN)

(21) Appl. No.: 16/620,917

(22) PCT Filed: Nov. 14, 2019
(86) PCT No.: PCT/CN2019/118505

§ 371 Date: Dec. 10, 2019

(30) Foreign Application Priority Data
Sep. 18, 2019 (CN) 201910878822.2

(51) Int. Cl. H01L 27/12; H01L 29/786

(52) U.S. Cl. CPC H01L 27/1244; H01L 27/1288; H01L 29/7869; H01L 27/1225

(57) ABSTRACT

The present invention relates to an array substrate, a fabricating method thereof, and a display device. On the one hand, the present invention provides a third metal layer including a second scanning signal line on the pixel electrode through a halftone mask process, thereby reducing the number of masks, thus saving production costs; on the other hand, the present invention avoids a buffer layer to be provided when the second scanning signal line is disposed under the gate, thereby further saving production costs.

### FIELD OF INVENTION

This invention relates to the field of display technologies, and in particular, to an array substrate, a fabricating method thereof, and a display device.

### BACKGROUND OF INVENTION

Display devices can convert computer data into various characters, numbers, symbols, or intuitive images and display them. Commands or data can be input into a computer using an input tool such as a keyboard, and the display content may be added, deleted, or changed by means of the hardware and software of the system at any time. Display devices are classified into types such as plasma, liquid crystals, light emitting diodes, and cathode ray tubes according to the display components used.

Large-sized, narrow-border display panel is a popular technology in the display industry. At present, there are many ways to achieve a narrow border. At present, the most mainstream is the gate on array (GOA) technology, which integrates a scan driver IC onto the array substrate. However, the GOA circuit requires much higher thin film transistor (TFT) device mobility and threshold voltage uniformity than driver and switching transistors in the pixel region. Therefore, there are few narrow-border panels equipped with oxide TFT GOA technology on the market. Another way to achieve a narrow border is to extend the scan line to the bottom of the panel, which saves space on both sides of the panel. The process of this method is very simple, only need to add a layer of metal wirings, which is the fastest way to realize narrow border technology.

### Technical Problems

Commonly used oxide TFT structures include back channel etch process (BCE) type, etch stop layer (ELS) process type, and top gate self-aligned type. Wherein BCE type devices have poor stability and limited application range; although the top-gate self-aligned oxide TFT has the advantages of small source/drain parasitic resistance, small parasitic capacitance, and good stress stability, the process is very difficult, and the source/drain conductor uniformity of a-IGZO is poor, and the on-state current of the TFT on the large-sized panel is highly divergent. ESL-type oxide TFT has the most mature technology and the best device uniformity in the three structures. Therefore, using ESL-type oxide TFT to make non-GOA narrow-border display panel is the simplest and most feasible method. However, the conventional ESL oxide TFT non-GOA type narrow border has many disadvantages such as a large number of masks and high production cost. Therefore, it needs to seek a novel array substrate to solve the above problems.

### Technical Solution

An object of the present invention is to provide an array substrate, a fabricating method thereof, and a display device, which can solve the disadvantages of many times of masks and high production cost in the prior art.

In order to solve the above problems, an embodiment of the present invention provides an array substrate, including a substrate, a first metal layer, a gate insulating layer, an active layer, an etch stop layer, a second metal layer, a passivation layer, a pixel electrode, and a third metal layer. Wherein the first metal layer includes a first scanning signal trace and a gate disposed on the substrate; the gate insulating layer is disposed on the first metal layer; the active layer is disposed on the gate insulating layer; the etch stop layer is disposed on the active layer; the second metal layer includes a source, a drain disposed on the etch stop layer and a data signal line connected to the drain; the source and the drain connect to the active layer through a plurality of first vias; the passivation layer is disposed on the second metal layer; the pixel electrode includes a first pixel electrode and a second pixel electrode disposed on the passivation layer; the first pixel electrode connects to the first scanning signal line through a second via; the second pixel electrode connects to the source through a third via; and the third metal layer includes a second scanning signal line disposed on the first pixel electrode.

Further, wherein constituent material of the first metal layer, the second metal layer, and the third metal layer comprises at least one of Mo, Al, Ti, or Cu.

Further, wherein constituent material of the gate insulating layer, the etch stop layer, and the passivation layer comprises at least one of SiO₂, SiNx, or Al₂O₃.

Further, wherein constituent material of the active layer comprises at least one of IGZO, IZO, or IZTO.

Another embodiment of the present invention further provides a method for fabricating the array substrate related in the present invention, wherein the method includes the steps of: step S1, providing a substrate; step S2, forming a first metal layer on the substrate and patterning it to form a first scanning signal line and a gate; step S3, forming a gate insulating layer on the first metal layer; step S4, forming an active layer on the gate insulating layer; step S5, forming a etch stop layer on the active layer; step S6, forming a second metal layer on the etch stop layer and patterning it to form a source, a drain, and a data signal line connected to the drain; wherein the source and the drain connect to the active layer through a plurality of first vias; step S7, forming a passivation layer on the second metal layer; step S8, forming a pixel electrode and a third metal layer on the passivation layer, wherein the pixel electrode includes a first pixel electrode connected to the first scanning signal line through a second via, and a second pixel electrode connected to the source through a third via; the third metal layer includes second scanning signal line disposed on the first pixel electrode.

Further, wherein the gate insulating layer in the step S3 is formed by plasma enhanced chemical vapor deposition or sputtering.

Further, wherein the etch stop layer in the step S5 is formed by plasma enhanced chemical vapor deposition or sputtering.

Further, wherein the passivation layer in the step S7 is formed by plasma enhanced chemical vapor deposition or sputtering.

Further, wherein the pixel electrode and the third metal layer in the step S8 are formed by a halftone mask process.

Another embodiment of the present invention further provides a display device, including a display panel, the display panel includes the array substrate of the present invention.

### Beneficial Effect

The present invention relates to an array substrate, a fabricating method thereof, and a display device. On the one hand, the present invention provides a third metal layer including a second scanning signal line on the pixel electrode through a halftone mask process, thereby reducing the number of masks, thus saving production costs; on the other hand, the present invention avoids a buffer layer to be provided when the second scanning signal line is disposed under the gate, thereby further saving production costs.

### DESCRIPTION OF DRAWINGS

In order to more clearly illustrate the technical solutions in the embodiments of the present invention, the drawings to be used in the embodiments will be briefly described below. It is obvious that the drawings in the following description are merely some of the embodiments of the present invention, and other drawings may be obtained based on these figures by those skilled in the art without any creative work.

FIG. 1 is a first schematic view of an array substrate of the present invention.

FIG. 2 is a second schematic view of an array substrate of the present invention.

FIG. 3 is a first schematic view showing the structure of an array substrate of the present invention.

FIG. 4 is a second schematic view showing the structure of an array substrate of the present invention.

FIG. 5 is a third schematic view showing the structure of an array substrate of the present invention.

FIG. 6 is a fourth schematic view showing the structure of an array substrate of the present invention.

FIG. 7 is a fifth schematic view showing the structure of an array substrate of the present invention.

Reference numbers and related parts in the drawings:

| 100 | array substrate | | |
|---|---|---|---|
| 1 | substrate | 2 | first metal layer |
| 3 | gate insulating layer | 4 | active layer |
| 5 | etch stop layer | 6 | second metal layer |
| 7 | passivation layer | 8 | pixel electrode |
| 9 | third metal layer | 10 | first via |
| 11 | second via | 12 | third via |
| 21 | first scanning signal line | 22 | gate |
| 61 | source | 62 | drain |
| 63 | data signal line | | |
| 81 | first pixel electrode | 82 | second pixel electrode |
| 91 | second scanning signal line | | |

### EMBODIMENTS OF THIS INVENTION

Preferred embodiments of the present invention with reference to the accompanying drawings are described below to illustrate that the invention can be practiced. These embodiments can fully introduce the technical content of the present invention to those skilled in the art, so that the technical content of the present invention is clearer and easier to be understood. However, the invention may be embodied in many different forms of embodiments, the scope of the invention is not limited to the embodiments mentioned herein, and the following description of the embodiments is not intended to limit the scope of the invention.

The directional terms mentioned in the present invention, such as up, down, front, back, left, right, inside, outside, side, etc., are only directions in the drawings, the directional terms used herein are used to explain and explain this invention, and they are not intended to limit the scope of the invention.

In the drawings, the components having similar structures are denoted by the same numerals. The structures and the components having similar function are denoted by similar numerals. In addition, to facilitate understanding and description, thickness and size of each of the components of the drawings are randomly shown, and the present disclosure does not limit thickness and size of each of the components.

When a first component is described as “on” a second component, the first component can be placed directly on the second component; there can also be an intermediate component, the first component is placed on the intermediate component, and the intermediate component is placed on the second component. When the first component is described as “installed on the second component” or “connected to the second component”, it should be understood as that the first component is directly installed on the second component or the first component is directly connected to the second component, or it should be understood as that the first component is indirectly installed on the second component via the intermediate component or the first component is indirectly connected to the second component via the intermediate component.

### Embodiment 1

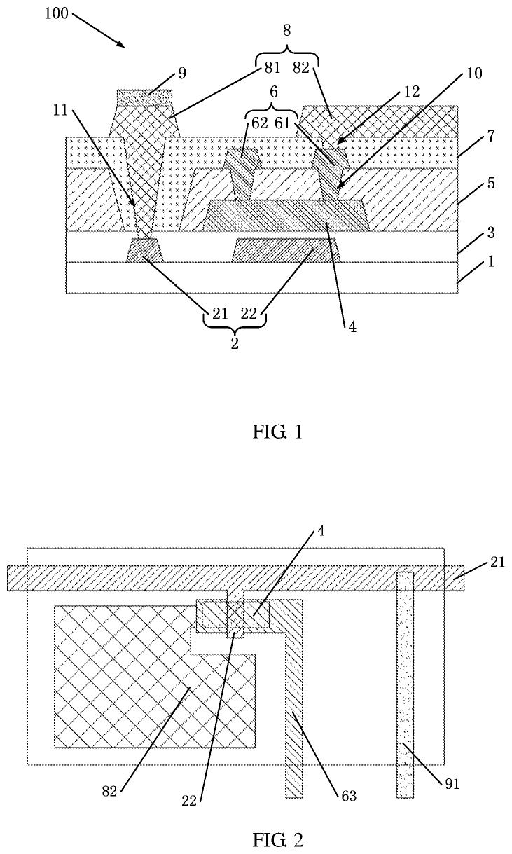

As shown in FIG. 1 and FIG. 2, an array substrate 100 includes a substrate 1, a first metal layer 2, a gate insulating layer 3, an active layer 4, an etch stop layer 5, a second metal layer 6, a passivation layer 7, a pixel electrode 8, and a third metal layer 9.

As shown in FIG. 1 and FIG. 2, wherein the first metal layer 2 includes a first scanning signal trace 21 and a gate 22 disposed on the substrate 1. Wherein constituent material of the first metal layer 2 comprises at least one of Mo, Al, Ti, or Cu. The first metal layer 2 thus produced has good electrical conductivity.

As shown in FIG. 1 and FIG. 2, the gate insulating layer 3 is disposed on the first metal layer 2. Constituent material of the gate insulating layer 3 comprises at least one of SiO₂, SiNx, or Al₂O₃. The gate insulating layer 3 thus produced has good insulation properties, and can prevent the gate 22 from coming into contact with the active layer 4 thereon very well, thereby avoiding a short circuit phenomenon and reducing product performance.

As shown in FIG. 1 and FIG. 2, the active layer 4 is disposed on the gate insulating layer 3. Constituent material of the active layer 4 may be selected from an amorphous oxide semiconductor material, and specifically may be at least one of IGZO, IZO, or IZTO.

As shown in FIG. 1 and FIG. 2, the etch stop layer 5 is disposed on the active layer 4. Constituent material of the etch stop layer 5 comprises at least one of SiO₂, SiNx, or Al₂O₃. Since the constituent material of the active layer 4 can be IGZO, and the characteristics of IGZO are unstable, the exposed IGZO is affected by the source/drain etching solution or the etching gas, and the device characteristics are deteriorated, so that the etch stop layer 5 is needed to be formed to protect the IGZO channel. The etching barrier layer 5 can also prevent the IGZO channel from being short-circuited by using the above materials, thereby avoiding the loss of switching characteristics.

As shown in FIG. 1 and FIG. 2, the second metal layer 6 includes a source 61, a drain 62 disposed on the etch stop layer 5 and a data signal line 63 connected to the drain 62; the source 61 and the drain 62 connect to the active layer 4 through a plurality of first vias 10. Wherein constituent material of the second metal layer 6 comprises at least one of Mo, Al, Ti, or Cu. The second metal layer 6 thus produced has good electrical conductivity.

As shown in FIG. 1 and FIG. 2, the passivation layer 7 is disposed on the second metal layer 6. Wherein constituent material of the passivation layer 7 comprises at least one of SiO₂, SiNx, or Al₂O₃. The passivation layer 7 thus produced has good insulation properties.

As shown in FIG. 1 and FIG. 2, the pixel electrode 8 includes a first pixel electrode 81 and a second pixel electrode 82 disposed on the passivation layer 7; the first pixel electrode 81 connects to the first scanning signal line 21 through a second via 11; the second pixel electrode 82 connects to the source 61 through a third via 12.

As shown in FIG. 1 and FIG. 2, the third metal layer 9 includes a second scanning signal line 91 disposed on the first pixel electrode 81. Wherein constituent material of the third metal layer 9 comprises at least one of Mo, Al, Ti, or Cu. In this embodiment, the third metal layer 9 including the second scanning signal line 91 is disposed on the first pixel electrode 81 by a halftone mask process, whereby the number of masks can be reduced, thereby saving production cost; on the other hand, the present embodiment also avoids a buffer layer to be disposed when the second scanning signal line 91 is disposed under the gate 22, thereby further saving production cost.

### Embodiment 2

The embodiment further provides a method for fabricating the array substrate 100 described in the embodiment 1.

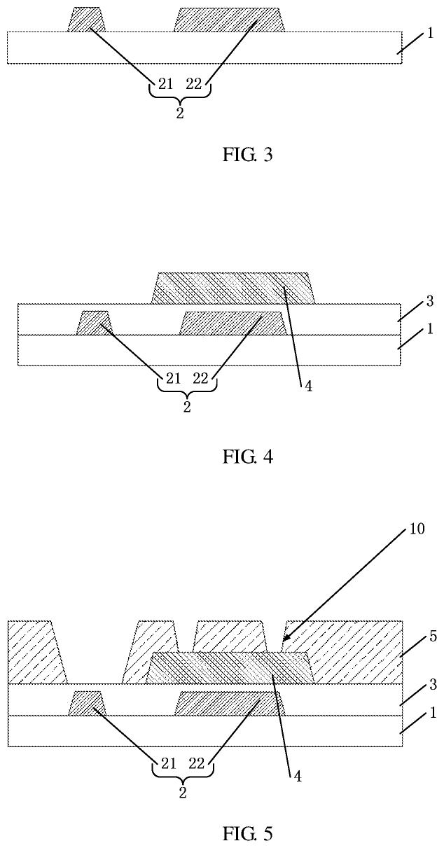

As shown in FIG. 3, step S1, providing a substrate 1; step S2, forming a first metal layer 2 on the substrate 1 and patterning it to form a first scanning signal line 21 and a gate 22.

As shown in FIG. 4, step S3, forming a gate insulating layer 3 on the first metal layer 2; step S4, forming an active layer 4 on the gate insulating layer 3. Wherein the gate insulating layer 3 may be formed by plasma enhanced chemical vapor deposition or sputtering.

The plasma enhanced chemical vapor deposition is a method in which a gas is excited in a chemical vapor deposition to generate a low temperature plasma and enhance the chemical activity of the reaction material to perform epitaxy. The method has the advantages of low deposition temperature, small influence on the structure and physical properties of the substrate, good film thickness and composition uniformity, compact film structure, less pinholes, strong adhesion of the film layer, and wide application range.

The sputtering process is a process in which a solid surface is bombarded by particles (ions or neutral atoms, molecules) with certain energy, and the atoms or molecules near the surface of the solid obtains sufficient energy to finally escape the surface of the solid.

As shown in FIG. 5, step S5, forming a etch stop layer 5 on the active layer 4; forming a plurality of first vias 10 in a region where the source and the drain to be formed, and forming a via at a position corresponding to the first scanning signal line 21 on the etch stop layer 5. Wherein the etch stop layer 5 may be formed by plasma enhanced chemical vapor deposition or sputtering.

The plasma enhanced chemical vapor deposition is a method in which a gas is excited in a chemical vapor deposition to generate a low temperature plasma and enhance the chemical activity of the reaction material to perform epitaxy. The method has the advantages of low deposition temperature, small influence on the structure and physical properties of the substrate, good film thickness and composition uniformity, compact film structure, less pinholes, strong adhesion of the film layer, and wide application range.

The sputtering process is a process in which a solid surface is bombarded by particles (ions or neutral atoms, molecules) with certain energy, and the atoms or molecules near the surface of the solid obtains sufficient energy to finally escape the surface of the solid.

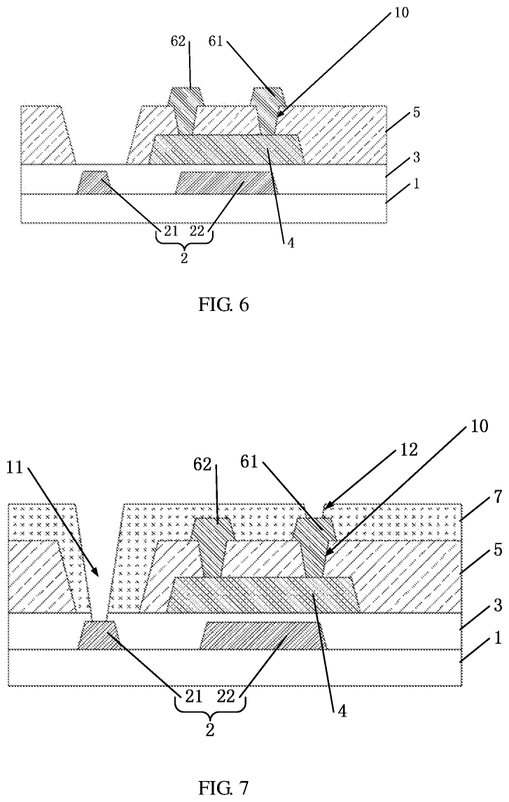

As shown in FIG. 2 and FIG. 6, step S6, forming a second metal layer 6 on the etch stop layer 5 and patterning it to form a source 61, a drain 62, and a data signal line 63 connected to the drain 62; wherein the source 61 and the drain 62 connect to the active layer 4 through a plurality of first vias 10.

As shown in FIG. 1, FIG. 2 and FIG. 7, step S7, forming a passivation layer 7 on the second metal layer 6; step S8, forming a pixel electrode 8 and a third metal layer 9 on the passivation layer 7, wherein the pixel electrode 8 comprises a first pixel electrode 81 connected to the first scanning signal line 21 through a second via 11, and a second pixel electrode 82 connected to the source 61 through a third via 12; the third metal layer 9 comprises second scanning signal line 91 disposed on the first pixel electrode 81.

The passivation layer in the step S7 is formed by plasma enhanced chemical vapor deposition or sputtering.

The plasma enhanced chemical vapor deposition is a method in which a gas is excited in a chemical vapor deposition to generate a low temperature plasma and enhance the chemical activity of the reaction material to perform epitaxy. The method has the advantages of low deposition temperature, small influence on the structure and physical properties of the substrate, good film thickness and composition uniformity, compact film structure, less pinholes, strong adhesion of the film layer, and wide application range.

The sputtering process is a process in which a solid surface is bombarded by particles (ions or neutral atoms, molecules) with certain energy, and the atoms or molecules near the surface of the solid obtains sufficient energy to finally escape the surface of the solid.

The pixel electrode 8 and the third metal layer 9 in the step S8 are formed by a halftone mask process, thereby reducing the number of masks, thus saving production costs; on the other hand, the array substrate 100 prepared in the present embodiment also avoids a buffer layer to be disposed when the second scanning signal line 91 is disposed under the gate 22, thereby further saving production cost.

Another embodiment of the present invention also provides a display device, including a display panel, the display panel includes the array substrate of the present invention.

The array substrate, the fabricating method thereof, and the display device provided by the present invention have been described in detail above. It should be understood that the exemplary embodiments described herein are to be considered as illustrative only, they are used to help to understand the method of the present invention and its core ideas, and they are not intended to limit the invention. Descriptions of features or aspects in each exemplary embodiment are generally considered to be applicable to similar features or aspects in other exemplary embodiments. While the invention has been described with reference to the preferred embodiments thereof, various modifications and changes can be made by those skilled in the art. The present invention is intended to cover such modifications and variations within the scope of the appended claims, and all modifications, equivalents, and improvements, etc. within the spirit and scope of the invention are intended to be included within the scope of the present invention.

What is claimed is:

1. An array substrate, comprising:
a substrate;
a first metal layer comprising a first scanning signal trace and a gate disposed on the substrate;
a gate insulating layer disposed on the first metal layer;
an active layer disposed on the gate insulating layer;
an etch stop layer disposed on the active layer;
a second metal layer comprising a source, a drain disposed on the etch stop layer and a data signal line connected to the drain;
wherein the source and the drain connect to the active layer through a plurality of first vias;
a passivation layer disposed on the second metal layer;
a pixel electrode comprising a first pixel electrode and a second pixel electrode disposed on the passivation layer;
wherein the first pixel electrode connects to the first scanning signal line through a second via;
wherein the second pixel electrode connects to the source through a third via; and
a third metal layer, comprising a second scanning signal line disposed on the first pixel electrode.

2. The array substrate as claimed in claim 1, wherein constituent material of the first metal layer, the second metal layer, and the third metal layer comprises at least one of Mo, Al, Ti, or Cu.

3. The array substrate as claimed in claim 1, wherein constituent material of the gate insulating layer, the etch stop layer, and the passivation layer comprises at least one of SiO₂, SiNx, or Al₂O₃.

4. The array substrate as claimed in claim 1, wherein constituent material of the active layer comprises at least one of IGZO, IZO, or IZTO.

5. A method for fabricating the array substrate as claimed in claim 1, wherein the method comprises the steps of:
step S1, providing a substrate;
step S2, forming a first metal layer on the substrate and patterning it to form a first scanning signal line and a gate;
step S3, forming a gate insulating layer on the first metal layer;
step S4, forming an active layer on the gate insulating layer;
step S5, forming a etch stop layer on the active layer;
step S6, forming a second metal layer on the etch stop layer and patterning it to form a source, a drain, and a data signal line connected to the drain; wherein the source and the drain connect to the active layer through a plurality of first vias;
step S7, forming a passivation layer on the second metal layer;
step S8, forming a pixel electrode and a third metal layer on the passivation layer, wherein the pixel electrode comprises a first pixel electrode connected to the first scanning signal line through a second via, and a second pixel electrode connected to the source through a third via; the third metal layer comprises second scanning signal line disposed on the first pixel electrode.

6. The method for fabricating the array substrate as claimed in claim 5, wherein the gate insulating layer in the step S3 is formed by plasma enhanced chemical vapor deposition or sputtering.

7. The method for fabricating the array substrate as claimed in claim 5, wherein the etch stop layer in the step S5 is formed by plasma enhanced chemical vapor deposition or sputtering.

8. The method for fabricating the array substrate as claimed in claim 5, wherein the passivation layer in the step S7 is formed by plasma enhanced chemical vapor deposition or sputtering.

9. The method for fabricating the array substrate as claimed in claim 5, wherein the pixel electrode and the third metal layer in the step S8 are formed by a halftone mask process.

10. A display device, comprising a display panel, the display panel comprising:
a substrate;
a first metal layer comprising a first scanning signal trace and a gate disposed on the substrate;
a gate insulating layer disposed on the first metal layer;
an active layer disposed on the gate insulating layer;
an etch stop layer disposed on the active layer;
a second metal layer comprising a source, a drain disposed on the etch stop layer and a data signal line connected to the drain;
wherein the source and the drain connect to the active layer through a plurality of first vias;
a passivation layer disposed on the second metal layer;
a pixel electrode comprising a first pixel electrode and a second pixel electrode disposed on the passivation layer;
wherein the first pixel electrode connects to the first scanning signal line through a second via;
wherein the second pixel electrode connects to the source through a third via; and
a third metal layer comprising a second scanning signal line disposed on the first pixel electrode.

11. The display device as claimed in claim 10, wherein constituent material of the first metal layer, the second metal layer, and the third metal layer comprises at least one of Mo, Al, Ti, or Cu.

12. The display device as claimed in claim 10, wherein constituent material of the gate insulating layer, the etch stop layer, and the passivation layer comprises at least one of SiO₂, SiNx, or Al₂O₃.

13. The display device as claimed in claim 10, wherein constituent material of the active layer comprises at least one of IGZO, IZO, or IZTO.
